(19) United States
(12) Patent Application Publication
(10) Pub. No.: US 2025/0066154 A1
(43) Pub. Date: Feb. 27, 2025

(54) WIRE SUPPLY MODULE AND WIRE BONDING MACHINE INCLUDING THE SAME

(71) Applicant: Samsung Electronics Co., Ltd., Suwon-si (KR)

(72) Inventors: Doojin KIM, Suwon-si (KR); Byongjoo KIM, Suwon-si (KR)

(73) Assignee: Samsung Electronics Co., Ltd., Suwon-si (KR)

(21) Appl. No.: 18/429,867

(22) Filed: Feb. 1, 2024

(30) Foreign Application Priority Data
Aug. 23, 2023 (KR) 10-2023-0110350

(51) Int. Cl. B65H 49/32; B65H 69/02; B65H 69/04; B65H 69/08; H01L 23/00

(52) U.S. Cl. CPC B65H 49/32; B65H 69/02; B65H 69/04; B65H 69/08; H01L 24/745; H01L 24/78; B65H 2406/31; B65H 2701/361; H01L 2224/745; H01L 2224/78601; H01L 2224/78631

(57) ABSTRACT

A wire supply module may include a plurality of spools and a joint machine. Wires may be wound on the spools. The joint machine may be arranged between the spools to join the wires to each other. The joint machine may include a housing, a jointer and a cutter. The housing may have a joint passage configured to receive ends of the wires. The jointer may be arranged in the housing to join the ends of the wires to each other. The cutter may be arranged in the housing to partially cut the joined ends of the wires. Thus, when all the wire on a currently used spool may be exhausted, the wire on another spool may be joined to the wire on the currently used spool so that the wire may be continuously supplied without a spool exchange.

### CROSS-RELATED APPLICATION

This application claims priority under 35 USC § 119 to Korean Patent Application No. 10-2023-0110350, filed on Aug. 23, 2023, in the Korean Intellectual Property Office (KIPO), the contents of which are herein incorporated by reference in their entirety.

### BACKGROUND

### 1. Field

Various example embodiments relate to a wire supply module and a wire bonding machine including the same. For example, some example embodiments relate to a wire supply module configured to supply a wire, which may be used for electrically connecting a package substrate with a semiconductor chip, to a capillary, and a wire bonding machine including the wire supply module.

### 2. Description of Related Arts

Generally, a wire bonding machine may electrically connect a package substrate with a semiconductor chip using a conductive wire. The wire bonding machine may include a heater, a capillary, a wire supply module, etc. The heater may heat the package substrate. The capillary may withdraw the conductive wire toward the package substrate and the semiconductor chip. The wire supply module may supply the conductive wire to the capillary.

According to related arts, the wire supply module may include a spool on which the wire may be wound. When all the wire on one spool may be used, it may be required to exchange the spool for a new spool on which a new wire may be wound. The spools may be manually exchanged by a worker so that efficiency of a wire bonding process may be decreased due to the spool exchange.

### SUMMARY

Various example embodiments provide a wire supply module that may be capable of continuously supplying a wire without a spool exchange.

Various example embodiments also provide a wire bonding machine including the above-mentioned wire supply module.

In some example embodiments, there may be provided a wire supply module including a plurality of spools on which wires wound and a joint machine arranged between the plurality of spools and configured to join the wires to each other. The joint machine includes a housing including a joint passage configured to receive ends of the wires, a jointer arranged in the housing and configured to join ends of the wires to each other, and a cutter arranged in the housing and configured to partially cut the joined ends of the wires.

In some example embodiments, there may be provided a wire supply module including a plurality of spools on which wires are wound and a joint machine arranged between the plurality of spools and configured to join the wires to each other. The joint machine includes a housing including a joint passage configured to receive ends of the wires, a supply passage configured to supply a joint material used for joining the ends of the wires to a jointer, and a suction passage configured to remove a residue generated in joining the ends of the wires, and a cutter arranged in the housing and configured to partially cut joined ends of the wires and the residue. The jointer is arranged in the housing and is configured to join the ends of the wires to each other.

In some example embodiments, there may be provided a wire bonding machine including a heater configured to heat a substrate with a semiconductor chip, a capillary arranged over the heater to withdraw wires and configured to connect the semiconductor chip with the substrate, and a wire supply module configured to supply the wires to the capillary. The wire supply module includes a plurality of spools on which the wires are wound and a joint machine arranged between the plurality of spools and configured to join the wires to each other. The joint machine includes a housing including a joint passage configured to receive ends of the wires, a jointer arranged in the housing and configured to join the ends of the wires to each other, and a cutter arranged in the housing and configured to partially cut joined ends of the wires.

### BRIEF DESCRIPTION OF THE DRAWINGS

Various example embodiments will be more clearly understood from the following detailed description taken in conjunction with the accompanying drawings. FIGS. 1 to 19 represent non-limiting, example embodiments as described herein.

FIG. 1 is a perspective view illustrating a wire bonding machine in accordance with example embodiments;

FIG. 2 is an enlarged cross-sectional view illustrating a wire supply module of the wire bonding machine in FIG. 1;

FIG. 3 is a front view illustrating a joint machine of the wire supply module in FIG. 2;

FIG. 4 is a rear view illustrating the joint machine in FIG. 3;

FIG. 5 is a cross-sectional view illustrating the joint machine in FIG. 3;

FIGS. 6 to 13 are views illustrating various jointers of the joint machine in FIG. 3;

FIG. 14 is a view illustrating an operating for detecting a joint portion between wires in the wire bonding machine in FIG. 1; and

FIGS. 15 to 19 are cross-sectional views illustrating an operation for excluding the joint portion in FIG. 14 from a wire bonding process.

### DETAILED DESCRIPTION

Hereinafter, various example embodiments will be explained in detail with reference to the accompanying drawings.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

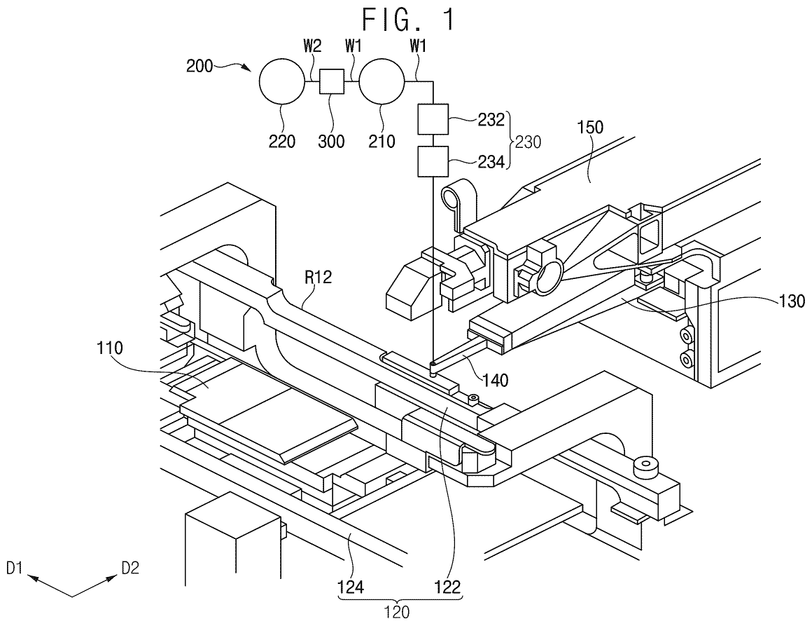

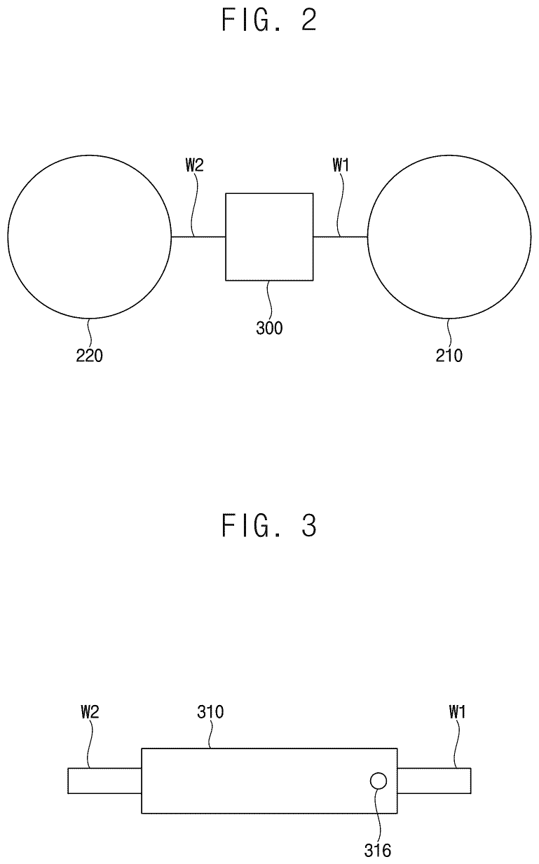

FIG. 1 is a perspective view illustrating a wire bonding machine in accordance with example embodiments and FIG. 2 is an enlarged cross-sectional view illustrating a wire supply module of the wire bonding machine in FIG. 1.

Referring to FIGS. 1 and 2, a wire bonding machine of example embodiments may electrically connect a substrate such as a printed circuit board (PCB), for example, a package substrate with a semiconductor chip using a conductive wire. The semiconductor chip may be attached to an upper surface of the package substrate. The wire bonding machine may bond a bonding pad of the semiconductor chip to a pad of the package substrate to electrically connect the semiconductor chip with the package substrate.

The wire bonding machine may include a heater 110, a rail 120, a capillary 140, a transducer 130, a camera module 150 and a wire supply module 200, but example embodiments are not limited thereto.

The heater 110 may heat the package substrate with the semiconductor chip. For example, the package substrate may be placed on an upper surface of the heater 110. Heat generated from the heater 110 may be applied to the package substrate and the semiconductor chip, for example, the pads of the package substrate and the semiconductor chip.

The rail 120 may be arranged over the heater 110. The package substrate with the semiconductor chip may be loaded into the heater 110 through the rail 120. Further, after a wire bonding process, the package substrate connected to the semiconductor chip via the wire may be unloaded from the heater 110 through the rail 120.

In some example embodiments, the rail 120 may include a front rail 122 and a rear rail 124. The front rail 122 and the rear rail 124 may be extended parallel to each other along a first horizontal direction D1. The heater 110 may be positioned between the front rail 122 and the rear rail 124. The front rail 122 may be positioned between the heater 110 and the capillary 140. For example, the front rail 122 may be arranged at a front side of the heater 110 oriented toward the capillary 140. In contrast, the rear rail 124 may be arranged at a rear side of the heater 110 opposite to the capillary 140.

The capillary 140 may be installed at the transducer 130. The transducer 130 may apply an ultrasonic wave to the capillary 140. Further, the transducer 130 may be moved along a second horizontal direction D2 substantially perpendicular to the first horizontal direction D1. Further, the transducer 130 may be moved along the first horizontal direction D1. Thus, the capillary 140 on the transducer 130 may also be moved along the first horizontal direction D1 and the second horizontal direction D2. For example, the capillary 140, which may be moved toward the heater 110 in the second horizontal direction D2, may enter into a space over the heater 110 crossing over the front rail 122.

The capillary 140 may withdraw the wire. One end of the wire withdrawn from the capillary 140 may be bonded to the bonding pad of the semiconductor chip in a ball shape. The other end of the wire may be stitch-bonded to the pad of the package substrate.

For example, the wire bonding machine may apply the wire extended from a lower end of the capillary 140 with a discharge flame to form the ball. The transducer 130 may move the capillary 140 to the semiconductor chip. The ultrasonic wave may be applied to the capillary 140 from the transducer 130 to form the ball at the lower end of the wire. The ball may be bonded to the bonding pad of the semiconductor chip. The transducer 130 may then move the capillary 140 to the package substrate. The ultrasonic wave may be applied to the capillary 140 to stitch-bond the other end of the wire to the package substrate. After the stitch-bonding, the wire may be cut from the pad of the package substrate. The above-mentioned bonding process may be repeated.

The camera module 150 may be arranged over the capillary 140. The camera module 150 may photograph the package substrate and the semiconductor chip bonded to each other by the wire withdrawn from the capillary 140. The wire bonding may be determined to be normal or not based on an image of the package substrate and the semiconductor chip photographed by the camera module 150.

The wire supply module 200 may be arranged over the capillary 140. The wire supply module 200 may supply the wire to the capillary 140. In some example embodiments, the wire supply module 200 may include a plurality of spools, a tension applier 230 and a joint machine 300, but example embodiments are not limited thereto.

The wires may be wound on the spools. In some example embodiments, the spools may include a first spool 210 and a second spool 220, but example embodiments are not limited thereto. For example, the spools may include at least three spools. When the spools may be two, a first wire W1 may be wound on the first spool 210. A second wire W2 may be wound on the second spool 220. Further, the first spool 210 may be used in a current wire bonding process. Thus, the second spool 220 may be a reserve spool. Therefore, a first end of the first wire W1 on the first spool 210 may be withdrawn to the capillary 140. A second end of the first wire W1 may be extended toward the second spool 220. A first end of the second wire W2 on the second spool 220 may be extended toward the first spool 210.

The tension applier 230 may apply a tensile force to the first wire W1 extended to the capillary 140. In some example embodiments, the tension applier 230 may include a horizontal tension applier 232 and a vertical tension applier 234. The horizontal tension applier 232 may apply a horizontal tensile force to the first wire W1. The vertical tension applier 234 may apply a vertical tensile force to the first wire W1.

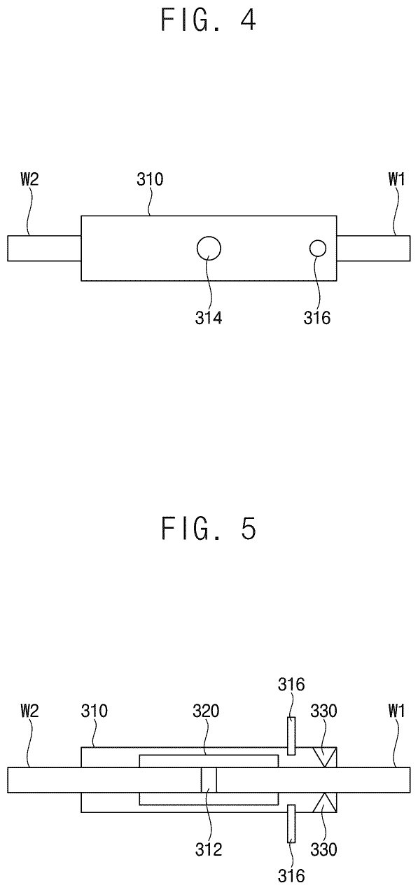

FIG. 3 is a front view illustrating a joint machine of the wire supply module in FIG. 2, FIG. 4 is a rear view illustrating the joint machine in FIG. 3 and FIG. 5 is a cross-sectional view illustrating the joint machine in FIG. 3.

Referring to FIGS. 3 to 5, the joint machine 300 may be arranged between the first spool 210 and the second spool 220. The joint machine 300 may join the ends of the first wire W1 and the second wire W2 to each other. For example, the joint machine 300 may join the second end of the first wire W1 to the first end of the second wire W2. When the first wire W1 wound on the first spool 210 may be almost exhausted, the joint machine 300 may join the first wire W1 and the second wire W2 to each other. Thus, the second wire W2 wound on the second spool 220 may be continuously supplied to the capillary 140 through the first spool 210. As a result, the wire may be continuously supplied to the capillary 140 without the spool exchange. In some example embodiments, the joint machine 300 may include a housing 310, a jointer 320 and a cutter 330, but example embodiments are not limited thereto.

The housing 310 may be arranged between the first spool 210 and the second spool 220. The housing 310 may be configured to receive the first wire W1 and the second wire W2. Thus, the housing 310 may have a cylindrical shape having a diameter longer than a diameter of the first wire W1 and the second wire W2, but example embodiments are not limited thereto. For example, the housing 310 may have a rectangular parallelepiped shape. The housing 310 may include a joint passage 312, a supply passage 314 and a suction passage 316.

The joint passage 312 may be configured to receive the first wire W1 and the second wire W2. The joint passage 312 may have a diameter for receiving the first wire W1 and the second wire W2. For example, the diameter of the joint passage 312 may be slightly longer than the diameter of the first wire W1 and the second wire W2. The joint passage 312 may be formed in the housing 310 along an axial direction of the housing 310. The joint passage 312 may be exposed through left and right side surfaces of the housing 310. The first wire W1 may be inserted into the joint passage 312 through the right side surface of the housing 310. The second wire W2 may be inserted into the joint passage 312 through the left side surface of the housing 310.

The supply passage 314 may supply a joint material, which may be used for joining the first wire W1 to the second wire W2, to the joint passage 312. The supply passage 314 may be formed in the housing 310 along a radial direction of the housing 310 substantially perpendicular to the axial direction, but example embodiments are not limited thereto. The supply passage 314 may be connected to the joint passage 312. Thus, the joint material may be provided to the joint passage 312 through the supply passage 314.

The suction passage 316 may remove a residue generated in joining the first wire W1 to the second wire W2. The suction passage 316 may be connected to a vacuum pump. Vacuum generated from the vacuum pump may be applied to the suction passage 316 to discharge the residue from the housing 310 through the suction passage 316. In some example embodiments, the suction passage 316 may be positioned between the jointer 320 and the cutter 330, but example embodiments are not limited thereto. Further, the suction passage 316 may include a pair of suction passages positioned over and under the second end of the first wire W1, but example embodiments are not limited thereto.

The jointer 320 may be arranged in the housing 310. The jointer 320 may join the ends of the first wire W1 and the second wire W2 to each other. In some example embodiments, the jointer 320 may include a heater. When the ends of the first wire W1 and the second wire W2 in the joint passage 312 may make contact with each other, the heater may apply heat to the ends of the first wire W1 and the second wire W2 to melt the ends of the first wire W1 and the second wire W2. The melted ends of the first wire W1 and the second wire W2 may be naturally cooled so that the ends of the first wire W1 and the second wire W2 may be converted into a solid state to join the first wire W1 and the second wire W2 to each other.

The cutter 330 may partially cut the jointer ends of the first wire W1 and the second wire W2. When the joint portion J between the first wire W1 and the second wire W2 may have a thickness greater than the diameter of the first wire W1 and the second wire W2, the cutter 330 may partially cut the joint portion J between the first wire W1 and the second wire W2 to provide the joint portion J with a diameter corresponding to the diameter of the first wire W1 and the second wire W2. Further, when the residue generated in joining the first wire W1 to the second wire W2 may remain on the joint portion J, the cutter 330 may cut the residue. In some example embodiments, the cutter 330 may include a pair of cutters positioned over and under the end of the first wire W1, but example embodiments are not limited thereto.

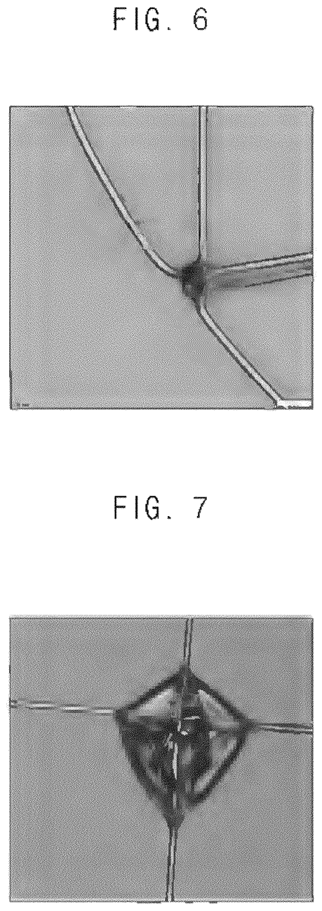

FIGS. 6 to 13 are views illustrating various jointers of the joint machine in FIG. 3.

Referring to FIG. 6, the jointer 320 of example embodiments may include a welding machine. The welding machine may weld the ends of the first wire W1 and the second wire W2 using a welding material. For example, the welding machine may be a direct bonding type using an instant welding. Alternatively, the welding machine may be an electric welding machine using an electrical spark.

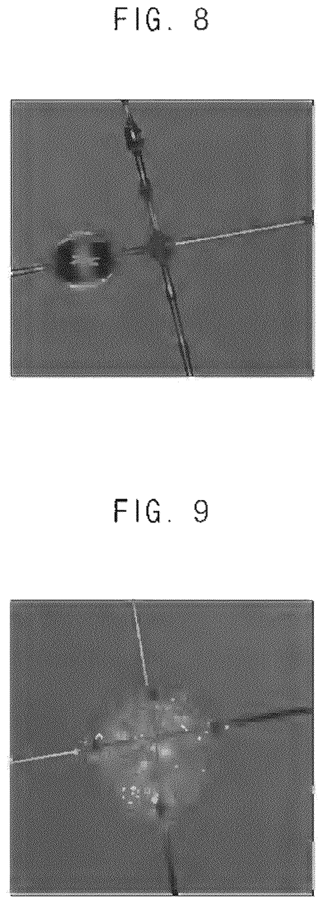

Referring to FIGS. 7 to 9, the jointer 320 of example embodiments may use glue. FIG. 7 may show an enamel resin as the glue. FIG. 8 may show an epoxy bond as the glue. FIG. 9 may show an acrylic bond as the glue. However, the glue may include other materials, but example embodiments are not limited within the above-mentioned materials.

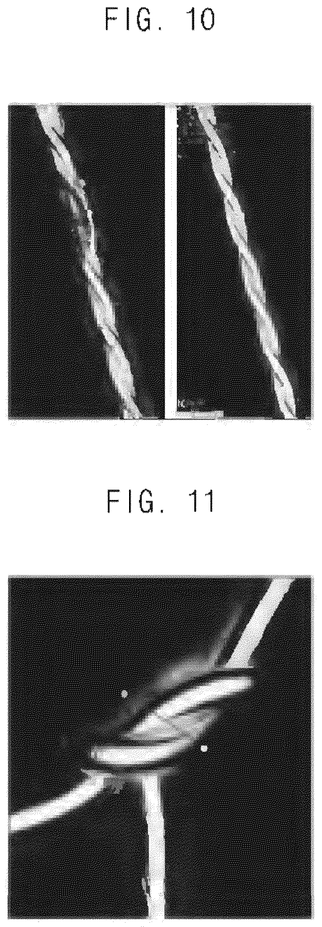

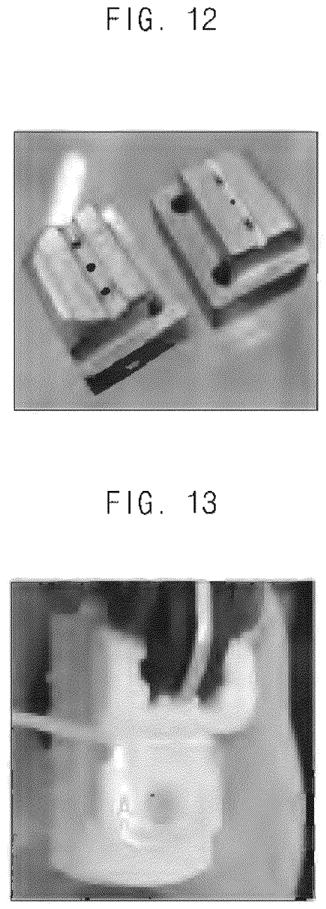

FIGS. 10 to 13, the jointer 320 of example embodiments may use a wire joint. FIG. 10 may show twisted ends of the first wire W1 and the second wire W2. FIG. 11 may show tied ends of the first wire W1 and the second wire W2. FIG. 12 may show joined ends of the first wire W1 and the second wire W2 using an air splicing. The air splicing may form a joint between the ends of the first wire W1 and the second wire W2 using a vibration by an ultrasonic wave welding. FIG. 13 may show joined ends of the first wire W1 and the second wire W2 using an air interlacing. The air interlacing may interlace the ends of the first wire W1 and the second wire W2 using compressed air.

In some example embodiments, the wire may be continuously supplied to the capillary 140 by joining the ends of the first wire W1 and the second wire W2 using the joint machine 300. However, the joint portion J between the first wire W1 and the second wire W2 may have a property different from a property of the second wire W2. For example, the joint portion J between the first wire W1 and the second wire W2 may have strength different from strength of the second wire W2. Further, the joint portion between the first wire W1 and the second wire W2 may have an electrical conductivity different from an electrical conductivity of the second wire W2. In some example embodiments, when the semiconductor chip and the substrate may be connected with each other using the joint portion J between the first wire W1 and the second wire W2, electrical reliability between the semiconductor chip and the substrate may be deteriorated.

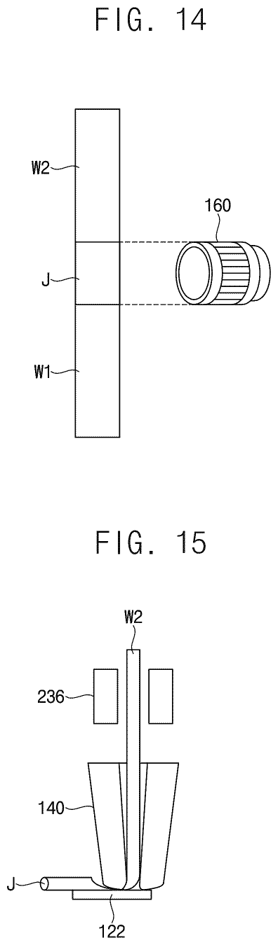

In order to prevent (or reduce) the deterioration of the electrical reliability, as shown in FIG. 14, the joint portion J between the first wire W1 and the second wire W2 may be detected using a camera 160. For example, when the ends of the first wire W1 and the second wire W2 may be joined to each other using the glue, the glue may be provided with a color different from a color of the first wire W1 and the second wire W2. Thus, the joint portion J with the glue may have a color different from the color of the first wire W1 and the second wire W2. The joint portion J may be detected from an image obtained by the camera 160. Alternatively, a grey color may be generated between the joint portion J and the first and second wires W1 and W2. Thus, the grey color may be shown on the image obtained by the camera 160.

FIGS. 15 to 19 are cross-sectional views illustrating an operation for excluding the joint portion in FIG. 14 from a wire bonding process.

Referring to FIG. 15, when the joint portion J may be withdrawn from the capillary 140, the capillary 140 may be downwardly moved to the front rail 122, not the substrate.

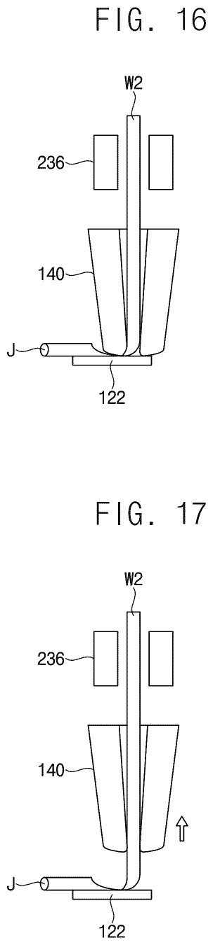

Referring to FIG. 16, the joint portion J may be bonded to the front rail 122.

Referring to FIG. 17, the capillary 140 may be upwardly moved to separate the second wire W2 from the joint portion J. For example, the joint portion J may remain on the front rail 122.

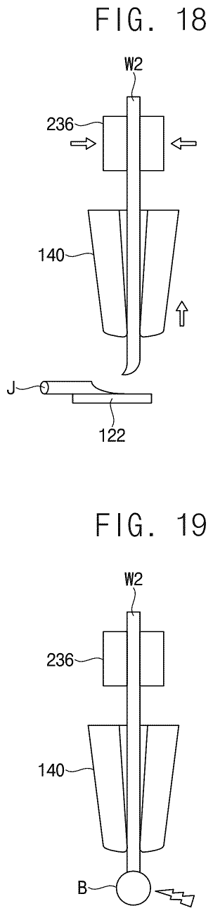

Referring to FIG. 18, the capillary 140 may be continuously ascended. A wire clamp 236 may horizontally press the second wire W2. As shown in FIG. 19, a ball B may be formed on a lower end of the second wire W2.

Therefore, in some example embodiments, the joint portion J may not be used in the wire bonding process. As a result, the deterioration of the electrical reliability between the semiconductor chip and the substrate caused by the joint portion J may be prevented (or reduced).

In some example embodiments, the joint machine between the spools may join the ends of the wires wound on the spools. Thus, when all the wire on a currently used spool may be exhausted, the wire on another spool may be joined to the wire on the currently used spool so that the wire may be continuously supplied without a spool exchange. For example, the joint machine may automatically join the wires to each other to improve efficiency of a wire bonding process.

The foregoing is illustrative of some example embodiments and is not to be construed as limiting thereof. Although a few example embodiments have been described, those skilled in the art will readily appreciate that many modifications are possible without departing from the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A wire supply module, comprising:
a plurality of spools on which wires are wound; and
a joint machine arranged between the plurality of spools and configured to join the wires to each other,
wherein the joint machine includes
a housing including a joint passage configured to receive ends of the wires;
a jointer arranged in the housing and configured to join the ends of the wires to each other; and
a cutter arranged in the housing and configured to partially cut the joined ends of the wires.

2. The wire supply module of claim 1, wherein the joint passage is extended in the housing from both side surfaces of the housing.

3. The wire supply module of claim 2, wherein the housing further comprises a supply passage for supplying a joint material used for joining the ends of the wires, to the jointer.

4. The wire supply module of claim 1, wherein the housing further comprises a suction passage configured to remove a residue generated in joining the ends of the wires.

5. The wire supply module of claim 4, wherein the suction passage is between the jointer and the cutter.

6. The wire supply module of claim 4, wherein the suction passage comprises a pair of passages over and under an end of a wire.

7. The wire supply module of claim 1, wherein the jointer comprises a heater.

8. The wire supply module of claim 1, wherein the jointer comprises a welding machine.

9. The wire supply module of claim 8, wherein the welding machine comprises an electric welding machine configured to use an electrical spark.

10. The wire supply module of claim 1, wherein the jointer is configured to join the ends of the wires to each other using a glue.

11. The wire supply module of claim 10, wherein the glue comprises an enamel resin, an epoxy bond or an acrylic bond.

12. The wire supply module of claim 1, wherein the joint machine is configured to join the ends of the wires by a wire joining.

13. The wire supply module of claim 12, wherein the wire joining comprises twisting or tying the ends of the wires.

14. The wire supply module of claim 12, wherein the wire joining comprises an air splicing or an air interlacing.

15. The wire supply module of claim 1, wherein the cutter comprises a pair of cutters arranged over and under an end of a wire.

16. A wire supply module, comprising:
a plurality of spools on which wires are wound; and
a joint machine arranged between the plurality of spools and configured to join the wires to each other,
wherein the joint machine includes
a housing including a joint passage configured to receive ends of the wires;
a supply passage configured to supply a joint material used for joining the ends of the wires to a jointer;
a suction passage configured to remove a residue generated in joining the ends of the wires; and
a cutter arranged in the housing and configured to partially cut joined ends of the wires and the residue, and
wherein the jointer is arranged in the housing and is configured to join the ends of the wires to each other.

17. The wire supply module of claim 16, wherein the joint passage is extended in the housing from both side surfaces of the housing.

18. The wire supply module of claim 16, wherein the suction passage is between the jointer and the cutter.

19. The wire supply module of claim 16, wherein the suction passage comprises a pair of passages over and under an end of a wire.

20. The wire supply module of claim 16, wherein the jointer comprises a heater.

21.-35. (canceled)
